(19) United States
(12) Patent Application Publication
(10) Pub. No.: US 2025/0230543 A1
(43) Pub. Date: Jul. 17, 2025

(54) SYSTEMS FOR DELIVERING PRECURSORS AND RELATED METHODS

(71) Applicant: ENTEGRIS, INC., Billerica, MA (US)

(72) Inventors: Bryan C. Hendrix, Danbury, CT (US); Lucas B. Henderson, Danbury, CT (US); Scott L. Battle, Cedar Park, TX (US); Florentina Popa, Houston, TX (US)

(21) Appl. No.: 19/030,029

(22) Filed: Jan. 17, 2025

Related U.S. Application Data
(60) Provisional application No. 63/621,907, filed on Jan. 17, 2024.

(51) Int. Cl. C23C 16/448

(52) U.S. Cl. CPC C23C 16/4481

(57) ABSTRACT

Systems for delivering precursors and related methods are provided. A system comprises at least one first container, at least one second container, at least one deposition chamber, a first conduit connecting the at least one first container to the at least one second container, and a second conduit connecting the at least one second container to the at least one deposition chamber. The first conduit is configured for delivering a vaporized precursor, at a first temperature, from the at least one first container to the at least one second container. The second conduit is configured for delivering the vaporized precursor, at a second temperature, from the at least one second container to the at least one deposition chamber. The first temperature is less than the second temperature.

### CROSS-REFERENCE TO RELATED APPLICATIONS

This application claims the benefit under 35 USC 119 of U.S. Provisional Patent Application No. 63/621,907, filed Jan. 17, 2024, the disclosure of which is hereby incorporated herein by reference in its entirety.

### FIELD

The present disclosure relates to systems for delivering precursors and related methods.

### BACKGROUND

Vapor deposition processes can involve delivering precursors to tools. At the tool, the precursors are deposited onto a substrate.

### SUMMARY

Some embodiments relate to a system. In some embodiments, the system comprises at least one first container. In some embodiments, the system comprises at least one second container. In some embodiments, the system comprises at least one deposition chamber. In some embodiments, the system comprises a first conduit connecting the at least one first container to the at least one second container. In some embodiments, the system comprises a second conduit connecting the at least one second container to the at least one deposition chamber. In some embodiments, the first conduit is configured for delivering a vaporized precursor, at a first temperature, from the at least one first container to the at least one second container. In some embodiments, the second conduit is configured for delivering the vaporized precursor, at a second temperature, from the at least one second container to the at least one deposition chamber. In some embodiments, the first temperature is less than the second temperature.

Some embodiments relate to a system. In some embodiments, the system comprises at least one first container. In some embodiments, the system comprises at least one second container. In some embodiments, the system comprises at least one deposition chamber. In some embodiments, the system comprises a first conduit connecting the at least one first container to the at least one second container. In some embodiments, the system comprises a second conduit connecting the at least one second container to the at least one deposition chamber. In some embodiments, the first conduit is configured for delivering a vaporized precursor, at a first pressure, from the at least one first container to the at least one second container. In some embodiments, the second conduit is configured for delivering the vaporized precursor, at a second pressure, from the at least one second container to the at least one deposition chamber. In some embodiments, the first pressure is less than the second pressure.

Some embodiments relate to a method. In some embodiments, the method comprises vaporizing a precursor, in a first container located in an area outside a fabrication area, to obtain a first vaporized precursor. In some embodiments, the method comprises transporting, at a first temperature, the first vaporized precursor through a first conduit to a second container located in an area in the fabrication area. In some embodiments, the method comprises condensing the first vaporized precursor in the second container to obtain a solid precursor. In some embodiments, the method comprises vaporizing the solid precursor, in the second container, to obtain a second vaporized precursor. In some embodiments, the method comprises transporting, at a second temperature, the second vaporized precursor through a second conduit to at least one deposition chamber located in an area in the fabrication area.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a schematic diagram of a system, according to some embodiments.

FIG. 2 is a flowchart of a method, according to some embodiments.

FIG. 3 is a schematic diagram of a system, according to some embodiments.

FIG. 4 is a schematic diagram of a system, according to some embodiments.

FIG. 5 is a schematic diagram of a system, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Precursors stored outside a fabrication area are delivered along long heated gas lines, or more generally conduits, to fabrication areas containing deposition chambers. The conditions (e.g., temperature and/or pressure and/or flow rate) under which the precursors are delivered through a conduit from outside the fabrication area to the fabrication area (e.g., to a deposition chamber) can lead to corrosion and particle creation, increasing servicing requirements for the conduits and systems generally, and introducing undesirable impurities into the precursor vapor. These conditions can also require more instruments and controls for maintaining the temperature along the length of the conduit to prevent, for example, undesirable condensation and/or undesirable thermal decomposition of the precursor, thereby increasing costs considerably.

Some embodiments provided herein overcome at least these challenges by providing systems and related methods that permit operation at lower temperatures and/or lower pressures and/or other conditions (e.g., flowrate), thereby minimizing the negative effects resulting from conventional systems and methods. The systems and methods provided herein minimize or avoid all together undesirable particle creation, while also extending the lifetime of systems for delivering precursors (e.g., from outside a fabrication area to a fabrication area or tool located in the fabrication area). In addition, in some embodiments, these long conduits can be evacuated or purged with inert gases when the conduits are not being used to deliver precursor vapor from containers to run/refill containers and/or tools at the fabrication area.

Systems for delivering precursors and related methods are provided. The precursors may be useful in deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The precursor may exist in a solid or liquid phase and may be vaporized (e.g., via heating) to obtain a vaporized precursor. In some embodiments, the precursor comprises at least one of dimethyl hydrazine, trimethyl aluminum (TMA), hafnium chloride (HfCl4), zirconium chloride (ZrCl4), indium trichloride, indium monochloride, aluminum trichloride, titanium iodide, tungsten carbonyl, Ba(DPM)2, bis dipivaloyl methanato strontium (Sr(DPM)2), TiO(DPM)2, tetra dipivaloyl methanato zirconium (Zr(DPM)4), decaborane, octadecaborane, boron-containing prescursors, indium-containing precursors, antimony-containing precursors, phosphorous-containing precursors, arsenic-containing precursors, precursors incorporating alkyl-amidinate ligands, organometallic precursors, alkali earth metals-RCp2, Sc-RCp3, Y-RCp3, lanthanide-RCp3, zirconium tertiary butoxide (Zr(t-OBu)4), tetrakisdiethylaminozirconium (Zr(NEt2)4), tetrakisdiethylaminohafnium (Hf(NEt2)4), tetrakis (dimethylamino) titanium (TDMAT), tertbutyliminotris (diethylamino) tantalum (TBTDET), pentakis (dimethylamino) tantalum (PDMAT), pentakis (ethylmethylamino) tantalum (PEMAT), tetrakisdimethylaminozirconium (Zr(NMe2)4), hafniumtertiarybutoxide (Hf(tOBu)4), xenon difluoride (XeF2), xenon tetrafluoride (XeF4), xenon hexafluoride (XeF6), or any combination thereof.

In some embodiments, the precursor comprises at least one of decaborane, hafnium tetrachloride, zirconium tetrachloride, indium trichloride, metalorganic β-diketonate complexes, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbonyl, or any combination thereof.

In some embodiments, the precursor comprises at least one of elemental metal, metal halides, metal oxyhalides, metalorganic complexes, or any combination thereof. For example, in some embodiments, the precursor material comprises, consists of, or consists essentially of, or is selected from the group consisting of, at least one of elemental boron, copper, phosphorus, decaborane, gallium halides, indium halides, antimony halides, arsenic halides, gallium halides, aluminum iodide, titanium iodide, MoO2Cl2, MoOCl4, MoCl5, WCl5, WOCl4, WCl6, cyclopentadienylcycloheptatrienyltitanium (CpTiCht), cyclooctatetraenecyclopenta-dienyltitanium, biscyclopentadienyltitanium-diazide, In(CH3)2(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the precursor comprises at least one of any type of source material that can be liquefied either by heating or solubilization in a solvent including, for example and without limitation, at least one of decaborane, (B10H14), pentaborane (B5H9), octadecaborane (B18H22), boric acid (H3BO3), SbCl3, SbCl5, or any combination thereof. In some embodiments, the precursor comprises at least one of at least one of AsCl3, AsBr3, AsF3, AsF5, As4O6, As2Se3m As2S2, As2S3, As2S5, As2Te3, B4H11, B4H10, B3H6N3, BBr3, BCl3, BF3·O(C2H5)2, BF3·HOCH3, B2H6, GeBr4, GeCl4, GeF4, GeH4, SiHCl3, SiCl4, SiH3Cl, Br2, BrF5, COCl2, COF2, Ni(CO)4, C8H24O4Si4, PH3, POCl3, PCl5, PF3, PFS, SbH3, SF4, Si(OC2H5)4, C4H16Si4O4, Si(CH3)4, SiH(CH3)3, TiCl4, WOF4, TaBr5, TaCl5, TaF5, Sb(C2H5)3, Sb(CH3)3, In(CH3)3, PBr5, PBr3, RuF5, or any combination thereof.

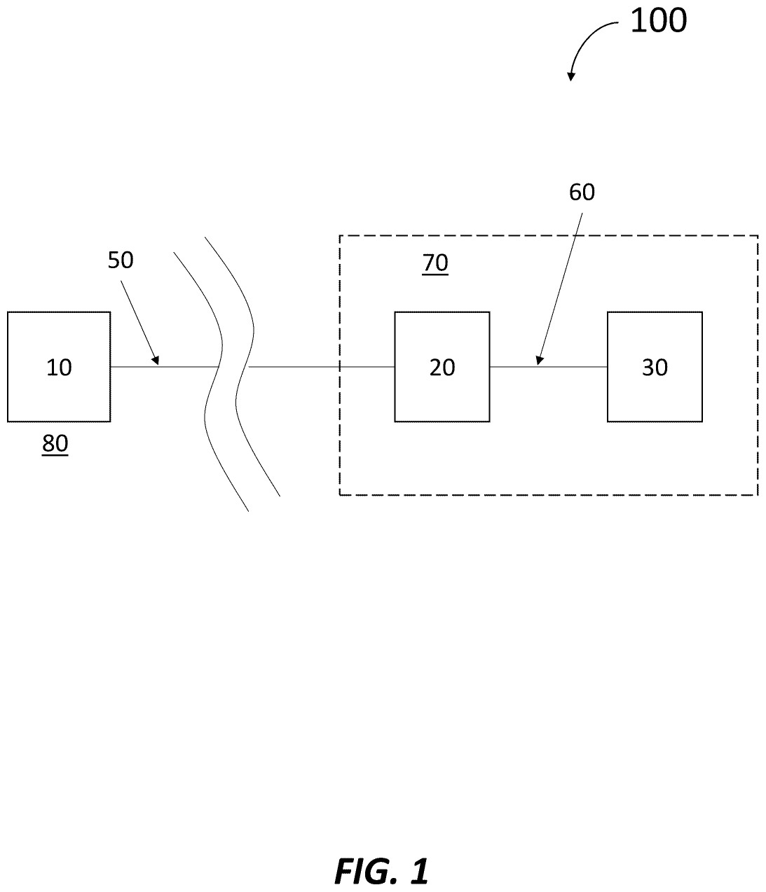

FIG. 1 is a schematic diagram of a system, according to some embodiments. As shown in FIG. 1, in some embodiments, the system 100 comprises at least one first container 10, at least one second container 20, and at least one deposition chamber 30. The system 100 comprises a first conduit 50 connecting the at least one first container 10 to the at least one second container 20. The system 100 comprises a second conduit 60 connecting the at least one second container 20 to the at least one deposition chamber 30. As shown in FIG. 1, in some embodiments, the at least one second container and the at least one deposition chamber 30 are located in a fabrication area 70 (e.g., “fab”). In some embodiments, the at least one first container 10 is located in a non-fabrication area 80 (e.g., located in an area outside the fabrication area, or “subfab”). In other embodiments, the at least one second container is located in a non-fabrication area, wherein the at least one second container is closer to the deposition chamber than the at least one first container.

The at least one first container 10 can contain a precursor. In some embodiments, the at least one first container 10 is configured to store the precursor. In some embodiments, the at least one first container 10 is configured to vaporize the precursor to obtain a vaporized precursor. In some embodiments, the at least one first container 10 is configured to deliver the vaporized precursor to the first conduit 50 for transport to the at least one second container 20. In some embodiments, the at least one second container 20 is configured to receive the vaporized precursor from the first conduit 50 and the at least one first container 10. In some embodiments, the vapor is recondensed in the second container 20 while the vapor is being received through the first conduit 50. In some embodiments, the at least one second container 20 is configured to store the precursor in solid phase or gas/vapor phase. In some embodiments, the at least one second container 20 is configured to vaporize the precursor to obtain a vaporized precursor. In some embodiments, the at least one second container 20 is configured to deliver the vaporized precursor to the second conduit 60 for transport to the at least one deposition chamber 30.

The at least one first container 10 can be configured to vaporize the precursor to obtain the vaporized precursor. In some embodiments, the at least one first container 10 is configured to heat the precursor to a temperature of 50° C. to 200° C., or any range or subrange between 50° C. and 200° C. For example, in some embodiments, the at least one first container 10 is configured to heat the precursor to a temperature of 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., 50° C. to 60° C., 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C.

In some embodiments, the at least one first container 10 is configured to vaporize the precursor under a pressure of 0.1 Torr to 600 Torr, or any range or subrange between 0.1 Torr and 600 Torr. In some embodiments, the at least one first container 10 is configured to vaporize the precursor under a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 10 Torr to 50 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, or 250 Torr to 300 Torr.

In some embodiments, the at least one first container 10 is configured to vaporize the precursor under a pressure of 0.1 Torr to 600 Torr, 0.1 Torr to 590 Torr, 0.1 Torr to 580 Torr, 0.1 Torr to 570 Torr, 0.1 Torr to 560 Torr, 0.1 Torr to 550 Torr, 0.1 Torr to 540 Torr, 0.1 Torr to 530 Torr, 0.1 Torr to 520 Torr, 0.1 Torr to 510 Torr, 0.1 Torr to 500 Torr, 0.1 Torr to 490 Torr, 0.1 Torr to 480 Torr, 0.1 Torr to 470 Torr, 0.1 Torr to 460 Torr, 0.1 Torr to 450 Torr, 0.1 Torr to 440 Torr, 0.1 Torr to 430 Torr, 0.1 Torr to 420 Torr, 0.1 Torr to 410 Torr, 0.1 Torr to 400 Torr, 0.1 Torr to 490 Torr, 0.1 Torr to 480 Torr, 0.1 Torr to 470 Torr, 0.1 Torr to 460 Torr, 0.1 Torr to 450 Torr, 0.1 Torr to 440 Torr, 0.1 Torr to 430 Torr, 0.1 Torr to 420 Torr, 0.1 Torr to 410 Torr, 0.1 Torr to 400 Torr, 0.1 Torr to 390 Torr, 0.1 Torr to 380 Torr, 0.1 Torr to 370 Torr, 0.1 Torr to 360 Torr, 0.1 Torr to 350 Torr, 0.1 Torr to 340 Torr, 0.1 Torr to 330 Torr, 0.1 Torr to 320 Torr, 0.1 Torr to 310 Torr, or 0.1 Torr to 300 Torr.

In some embodiments, the at least one first container 10 is configured to vaporize the precursor under a pressure of 300 Torr to 600 Torr, 310 Torr to 600 Torr, 320 Torr to 600 Torr, 330 Torr to 600 Torr, 340 Torr to 600 Torr, 350 Torr to 600 Torr, 360 Torr to 600 Torr, 370 Torr to 600 Torr, 380 Torr to 600 Torr, 390 Torr to 600 Torr, 400 Torr to 600 Torr, 410 Torr to 600 Torr, 420 Torr to 600 Torr, 430 Torr to 600 Torr, 440 Torr to 600 Torr, 450 Torr to 600 Torr, 460 Torr to 600 Torr, 470 Torr to 600 Torr, 480 Torr to 600 Torr, 490 Torr to 600 Torr, 500 Torr to 600 Torr, 510 Torr to 600 Torr, 520 Torr to 600 Torr, 530 Torr to 600 Torr, 540 Torr to 600 Torr, 550 Torr to 600 Torr, 560 Torr to 600 Torr, 570 Torr to 600 Torr, 580 Torr to 600 Torr, or 590 Torr to 600 Torr.

The at least one second container 20 can be configured to condense the vaporized precursor for storing the precursor. In some embodiments, the at least one second container 20 is configured to cool the precursor to a temperature of 0° C. to 100° C., or any range or subrange between 0° C. and 100° C. In some embodiments, the at least one second container 20 is configured to cool the precursor to a temperature of 0° C. to 90° C., 0° C. to 80° C., 0° C. to 70° C., 0° C. to 60° C., 0° C. to 50° C., 0° C. to 40° C., 0° C. to 30° C., 0° C. to 20° C., 0° C. to 10° C., 10° C. to 100° C., 20° C. to 100° C., 30° C. to 100° C., 40° C. to 100° C., 50° C. to 100° C., 60° C. to 100° C., 70° C. to 100° C., 80° C. to 100° C., or 90° C. to 100° C.

The at least one second container 20 can be configured to vaporize the precursor to obtain the vaporized precursor. In some embodiments, the at least one second container 20 is configured to heat the precursor to a temperature of 100° C. to 300° C., or any range or subrange between 100° C. and 300° C. In some embodiments, the at least one second container 20 is configured to heat the precursor to a temperature of 100° C. to 290° C., 100° C. to 280° C., 100° C. to 270° C., 100° C. to 260° C., 100° C. to 250° C., 100° C. to 240° C., 100° C. to 230° C., 100° C. to 220° C., 100° C. to 210° C., 100° C. to 200° C., 100° C. to 190° C., 100° C. to 180° C., 100° C. to 170° C., 100° C. to 160° C., 100° C. to 150° C., 100° C. to 140° C., 100° C. to 130° C., 100° C. to 120° C., 100° C. to 110° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

In some embodiments, the at least one second container 20 is configured to condense the precursor under a pressure of 0.1 Torr to 600 Torr, or any range or subrange between 0.1 Torr and 600 Torr. In some embodiments, the at least one second container 20 is configured to condense the precursor under a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 10 Torr to 50 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, or 250 Torr to 300 Torr.

In some embodiments, the at least one second container 20 is configured to vaporize the precursor under a pressure of 0.1 Torr to 600 Torr, or any range or subrange between 0.1 Torr and 600 Torr. In some embodiments, the at least one second container 20 is configured to vaporize the precursor under a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 10 Torr to 50 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, or 250 Torr to 300 Torr.

In some embodiments, the at least one second container 20 is configured to vaporize and/or condense the precursor under a pressure of 0.1 Torr to 600 Torr, 0.1 Torr to 590 Torr, 0.1 Torr to 580 Torr, 0.1 Torr to 570 Torr, 0.1 Torr to 560 Torr, 0.1 Torr to 550 Torr, 0.1 Torr to 540 Torr, 0.1 Torr to 530 Torr, 0.1 Torr to 520 Torr, 0.1 Torr to 510 Torr, 0.1 Torr to 500 Torr, 0.1 Torr to 490 Torr, 0.1 Torr to 480 Torr, 0.1 Torr to 470 Torr, 0.1 Torr to 460 Torr, 0.1 Torr to 450 Torr, 0.1 Torr to 440 Torr, 0.1 Torr to 430 Torr, 0.1 Torr to 420 Torr, 0.1 Torr to 410 Torr, 0.1 Torr to 400 Torr, 0.1 Torr to 490 Torr, 0.1 Torr to 480 Torr, 0.1 Torr to 470 Torr, 0.1 Torr to 460 Torr, 0.1 Torr to 450 Torr, 0.1 Torr to 440 Torr, 0.1 Torr to 430 Torr, 0.1 Torr to 420 Torr, 0.1 Torr to 410 Torr, 0.1 Torr to 400 Torr, 0.1 Torr to 390 Torr, 0.1 Torr to 380 Torr, 0.1 Torr to 370 Torr, 0.1 Torr to 360 Torr, 0.1 Torr to 350 Torr, 0.1 Torr to 340 Torr, 0.1 Torr to 330 Torr, 0.1 Torr to 320 Torr, 0.1 Torr to 310 Torr, or 0.1 Torr to 300 Torr.

In some embodiments, the at least one second container 20 is configured to vaporize and/or condense the precursor under a pressure of 300 Torr to 600 Torr, 310 Torr to 600 Torr, 320 Torr to 600 Torr, 330 Torr to 600 Torr, 340 Torr to 600 Torr, 350 Torr to 600 Torr, 360 Torr to 600 Torr, 370 Torr to 600 Torr, 380 Torr to 600 Torr, 390 Torr to 600 Torr, 400 Torr to 600 Torr, 410 Torr to 600 Torr, 420 Torr to 600 Torr, 430 Torr to 600 Torr, 440 Torr to 600 Torr, 450 Torr to 600 Torr, 460 Torr to 600 Torr, 470 Torr to 600 Torr, 480 Torr to 600 Torr, 490 Torr to 600 Torr, 500 Torr to 600 Torr, 510 Torr to 600 Torr, 520 Torr to 600 Torr, 530 Torr to 600 Torr, 540 Torr to 600 Torr, 550 Torr to 600 Torr, 560 Torr to 600 Torr, 570 Torr to 600 Torr, 580 Torr to 600 Torr, or 590 Torr to 600 Torr.

The at least one deposition chamber may be configured to receive the vaporized precursor at a deposition temperature and/or a deposition pressure. The deposition temperature may be a temperature of 200° C. to 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The deposition pressure may be a pressure of 0.001 Torr to 600 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

In some embodiments, the deposition pressure may be a pressure of 0.1 Torr to 600 Torr, 0.1 Torr to 590 Torr, 0.1 Torr to 580 Torr, 0.1 Torr to 570 Torr, 0.1 Torr to 560 Torr, 0.1 Torr to 550 Torr, 0.1 Torr to 540 Torr, 0.1 Torr to 530 Torr, 0.1 Torr to 520 Torr, 0.1 Torr to 510 Torr, 0.1 Torr to 500 Torr, 0.1 Torr to 490 Torr, 0.1 Torr to 480 Torr, 0.1 Torr to 470 Torr, 0.1 Torr to 460 Torr, 0.1 Torr to 450 Torr, 0.1 Torr to 440 Torr, 0.1 Torr to 430 Torr, 0.1 Torr to 420 Torr, 0.1 Torr to 410 Torr, 0.1 Torr to 400 Torr, 0.1 Torr to 490 Torr, 0.1 Torr to 480 Torr, 0.1 Torr to 470 Torr, 0.1 Torr to 460 Torr, 0.1 Torr to 450 Torr, 0.1 Torr to 440 Torr, 0.1 Torr to 430 Torr, 0.1 Torr to 420 Torr, 0.1 Torr to 410 Torr, 0.1 Torr to 400 Torr, 0.1 Torr to 390 Torr, 0.1 Torr to 380 Torr, 0.1 Torr to 370 Torr, 0.1 Torr to 360 Torr, 0.1 Torr to 350 Torr, 0.1 Torr to 340 Torr, 0.1 Torr to 330 Torr, 0.1 Torr to 320 Torr, 0.1 Torr to 310 Torr, 0.1 Torr to 300 Torr, 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 1 Torr, or any range or subrange between 0.1 Torr to 600 Torr.

In some embodiments, the deposition pressure may be a pressure of 1 Torr to 600 Torr, 10 Torr to 600 Torr, 20 Torr to 600 Torr, 30 Torr to 600 Torr, 40 Torr to 600 Torr, 50 Torr to 600 Torr, 60 Torr to 600 Torr, 70 Torr to 600 Torr, 80 Torr to 600 Torr, 90 Torr to 600 Torr, 100 Torr to 600 Torr, 110 Torr to 600 Torr, 120 Torr to 600 Torr, 130 Torr to 600 Torr, 140 Torr to 600 Torr, 150 Torr to 600 Torr, 160 Torr to 600 Torr, 170 Torr to 600 Torr, 180 Torr to 600 Torr, 190 Torr to 600 Torr, 200 Torr to 600 Torr, 210 Torr to 600 Torr, 220 Torr to 600 Torr, 230 Torr to 600 Torr, 240 Torr to 600 Torr, 250 Torr to 600 Torr, 260 Torr to 600 Torr, 270 Torr to 600 Torr, 280 Torr to 600 Torr, 290 Torr to 600 Torr, 300 Torr to 600 Torr, 310 Torr to 600 Torr, 320 Torr to 600 Torr, 330 Torr to 600 Torr, 340 Torr to 600 Torr, 350 Torr to 600 Torr, 360 Torr to 600 Torr, 370 Torr to 600 Torr, 380 Torr to 600 Torr, 390 Torr to 600 Torr, 400 Torr to 600 Torr, 410 Torr to 600 Torr, 420 Torr to 600 Torr, 430 Torr to 600 Torr, 440 Torr to 600 Torr, 450 Torr to 600 Torr, 460 Torr to 600 Torr, 470 Torr to 600 Torr, 480 Torr to 600 Torr, 490 Torr to 600 Torr, 500 Torr to 600 Torr, 510 Torr to 600 Torr, 520 Torr to 600 Torr, 530 Torr to 600 Torr, 540 Torr to 600 Torr, 550 Torr to 600 Torr, 560 Torr to 600 Torr, 570 Torr to 600 Torr, 580 Torr to 600 Torr, 590 Torr to 600 Torr, or any range or subrange between 0.1 Torr and 600 Torr.

In some embodiments, the deposition temperature and/or the deposition pressure of the at least one deposition chamber 30 is greater than the temperature and/or pressure of the at least one second container 20. In some embodiments, the deposition temperature and/or the deposition pressure of the at least one deposition chamber 30 is less than the temperature and/or pressure of the at least one second container 20. In some embodiments, the temperature and/or pressure of the at least one second container 20 is greater than the temperature and/or pressure of the at least one first container 10. In some embodiments, the temperature and/or pressure of the at least one second container 20 is less than the temperature and/or pressure of the at least one first container 10.

The first conduit may be configured to deliver the vaporized precursor, at a first temperature, from the at least one first container to the at least one second container. The second conduit may be configured to deliver the vaporized precursor, at a second temperature, from the at least one second container to the at least one deposition chamber. In some embodiments, the first temperature is less than the second temperature. In some embodiments, the first temperature is 1% to 99%, 5% to 99%, 10% to 99%, 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, 95% to 99%, 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, or 5% to 10% less than the second temperature.

The first temperature may be a temperature of 50° C. to 200° C., or any range or subrange between 50° C. and 200° C. In some embodiments, the first temperature is a temperature of 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., or 50° C. to 60° C. In some embodiments, the first temperature is a temperature of 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C. In some embodiments, the first temperature is a first set point temperature, wherein an observed temperature in the first conduit or of the first conduit is within any one or more of the aforementioned ranges. The first set point temperature may be any temperature within the range of 50° C. to 200° C. In some embodiments, the range of observed temperatures above and below the first set point temperature is 5° C. 10° C., 15° C., 20° C., 25° C., or 30° C.

The second temperature may be a temperature of 100° C. to 300° C., or any range or subrange between 100° C. and 300° C. In some embodiments, the second temperature is a temperature of 100° C. to 290° C., 100° C. to 280° C., 100° C. to 270° C., 100° C. to 260° C., 100° C. to 250° C., 100° C. to 240° C., 100° C. to 230° C., 100° C. to 220° C., 100° C. to 210° C., 100° C. to 200° C., 100° C. to 190° C., 100° C. to 180° C., 100° C. to 170° C., 100° C. to 160° C., 100° C. to 150° C., 100° C. to 140° C., 100° C. to 130° C., 100° C. to 120° C., 100° C. to 110° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C. In some embodiments, the second temperature is a second set point temperature, wherein an observed temperature in the second conduit or of the second conduit is within any one or more of the aforementioned ranges. The second set point temperature may be any temperature within the range of 100° C. to 300° C. In some embodiments, the range of observed temperatures above and below the first set point temperature is 5° C. 10° C., 15° C., 20° C., 25° C., 30° C., 35° C., 40° C., or 45° C.

The first conduit may be configured to deliver the vaporized precursor, at a first pressure, from the at least one first container to the at least one second container. The second conduit may be configured to deliver the vaporized precursor, at a second pressure, from the at least one second container to the at least one deposition chamber. In some embodiments, the first pressure is less than the second pressure. In some embodiments, the first pressure is 1% to 99%, 5% to 99%, 10% to 99%, 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, 95% to 99%, 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, or 5% to 10% less than the second pressure.

The first pressure may be a pressure of 0.1 Torr to 300 Torr, or any range or subrange between 0.1 Torr and 300 Torr. In some embodiments, the first pressure is a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 10 Torr to 50 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, 250 Torr to 300 Torr. In some embodiments, the first pressure is a first set point pressure, wherein an observed pressure in the first conduit or of the first conduit is within any one or more of the aforementioned ranges. The first set point pressure may be any pressure within the range of 0.1 Torr to 100 Torr. In some embodiments, the range of observed pressures above and below the first set point pressure is 1 Torr, 10 Torr, 15 Torr, 20 Torr, 25 Torr, or 30 Torr.

The second pressure may be a pressure of 0.1 Torr to 300 Torr, or any range or subrange between 0.1 Torr and 300 Torr. In some embodiments, the second pressure is a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, or 250 Torr to 300 Torr. In some embodiments, the second pressure is a second set point pressure, wherein an observed pressure in the second conduit or of the second conduit is within any one or more of the aforementioned ranges. The second set point pressure may be any pressure within the range of 0.1 Torr to 100 Torr. In some embodiments, the range of observed pressures above and below the second set point pressure is 1 Torr, 10 Torr, 15 Torr, 20 Torr, 25 Torr, or 30 Torr.

The first conduit may have a length that is greater than a length of the second conduit. For example, in some embodiments, the first conduit has a length that is 1.1 times to 100 times a length of the second conduit. In some embodiments, the first conduit has a length that is at least 1.1 times, at least 1.2 times, at least 1.3 times, at least 1.4 times, at least 1.5 times, at least 1.6 times, at least 1.7 times, at least 1.8 times, at least 1.9 times, at least 2 times, at least 2.1 times, at least 2.2 times, at least 2.3 times, at least 2.4 times, at least 2.5 times, at least 2.6 times, at least 2.7 times, at least 2.8 times, at least 2.9 times, at least 3 times, at least 3.1 times, at least 3.2 times, at least 3.3 times, at least 3.4 times, at least 3.5 times, at least 3.6 times, at least 3.7 times, at least 3.8 times, at least 3.9 times, at least 4 times, at least 4.1 times, at least 4.2 times, at least 4.3 times, at least 4.4 times, at least 4.5 times, at least 4.6 times, at least 4.7 times, at least 4.8 times, at least 4.9 times, at least 5 times, at least 5.5 times, at least 6 times, at least 6.5 times, at least 7 times, at least 7.5 times, at least 8 times, at least 8.5 times, at least 9 times, at least 9.5 times, at least 10 times, at least 20 times, at least 50 times, at least 70 times, up to 100 times a length of the second conduit.

The flowrate through the first conduit 50 may range from 50 sccm to 1200 sccm, or any range or subrange between 50 sccm and 1200 sccm. For example, in some embodiments, the flowrate through the first conduit 50 is 50 sccm to 1100 sccm, 50 sccm to 1000 sccm, 50 sccm to 900 sccm, 50 sccm to 800 sccm, 50 sccm to 700 sccm, 50 sccm to 600 sccm, 50 sccm to 500 sccm, 50 sccm to 400 sccm, 50 sccm to 300 sccm, 50 sccm to 200 sccm, 50 sccm to 100 sccm, 100 sccm to 1200 sccm, 200 sccm to 1200 sccm, 300 sccm to 1200 sccm, 400 sccm to 1200 sccm, 500 sccm to 1200 sccm, 600 sccm to 1200 sccm, 700 sccm to 1200 sccm, 800 sccm to 1200 sccm, 900 sccm to 1200 sccm, 1000 sccm to 1200 sccm, or 1100 sccm to 1200 sccm.

The flowrate through the second conduit 60 may range from 50 sccm to 1200 sccm, or any range or subrange between 50 sccm and 1200 sccm. For example, in some embodiments, the flowrate through the second conduit 60 is 50 sccm to 1100 sccm, 50 sccm to 1000 sccm, 50 sccm to 900 sccm, 50 sccm to 800 sccm, 50 sccm to 700 sccm, 50 sccm to 600 sccm, 50 sccm to 500 sccm, 50 sccm to 400 sccm, 50 sccm to 300 sccm, 50 sccm to 200 sccm, 50 sccm to 100 sccm, 100 sccm to 1200 sccm, 200 sccm to 1200 sccm, 300 sccm to 1200 sccm, 400 sccm to 1200 sccm, 500 sccm to 1200 sccm, 600 sccm to 1200 sccm, 700 sccm to 1200 sccm, 800 sccm to 1200 sccm, 900 sccm to 1200 sccm, 1000 sccm to 1200 sccm, or 1100 sccm to 1200 sccm.

In some embodiments, the system 100 does not comprise a carrier gas source. In some embodiments, the system 100 is configured to transport the vaporized precursor by drawing the vaporized precursor through the first conduit 50 and/or the second conduit 60. In some embodiments, the system 100 further comprises, for example, a vacuum or a pump sufficient for drawing the vaporized precursor through the first conduit 50 and/or the second conduit 60. In some embodiments, the system 100 further comprises at least one vacuum, wherein the at least one vacuum is connected to at least one of the first conduit, the second conduit, or any combination thereof, wherein the at least one vacuum is configured for drawing the vaporized precursor through at least one of the first conduit (e.g., from the at least one first container 10 to the at least one second container 20), the second conduit (e.g., from the at least one second container 20 to the at least one deposition chamber 30), or any combination thereof.

In some embodiments, the system 100 further comprises a plurality of temperature controllers located along a length of the first conduit and/or the second conduit. In some embodiments, each of the plurality of temperature controllers is located at least 1 foot apart, at least 2 feet apart, at least 3 feet apart, at least 4 feet apart, at least 5 feet apart, at least 6 feet apart, at least 7 feet apart, at least 8 feet apart, at least 9 feet apart, at least 10 feet apparat, at least 15 feet apart, at least 20 feet apart, or longer, along a length of the first conduit. In some embodiments, each of the plurality of temperature controllers is configured to maintain the first conduit at the first temperature. In some embodiments, the first temperature is a first set point temperature. In some embodiments, each of the plurality of temperature controllers is located at least 1 foot apart, at least 2 feet apart, at least 3 feet apart, at least 4 feet apart, at least 5 feet apart, at least 6 feet apart, at least 7 feet apart, at least 8 feet apart, at least 9 feet apart, at least 10 feet apparat, at least 15 feet apart, at least 20 feet apart, or longer, along a length of the second conduit. In some embodiments, each of the plurality of temperature controllers is configured to maintain the second conduit at the second temperature. In some embodiments, the second temperature is a second set point temperature. In some embodiments, in comparison to conventional systems, the system 100 unexpectedly requires fewer temperature controllers than conventional systems. In some embodiments, pressure controllers are used in addition to or in the alternative to the temperature controllers disclosed herein.

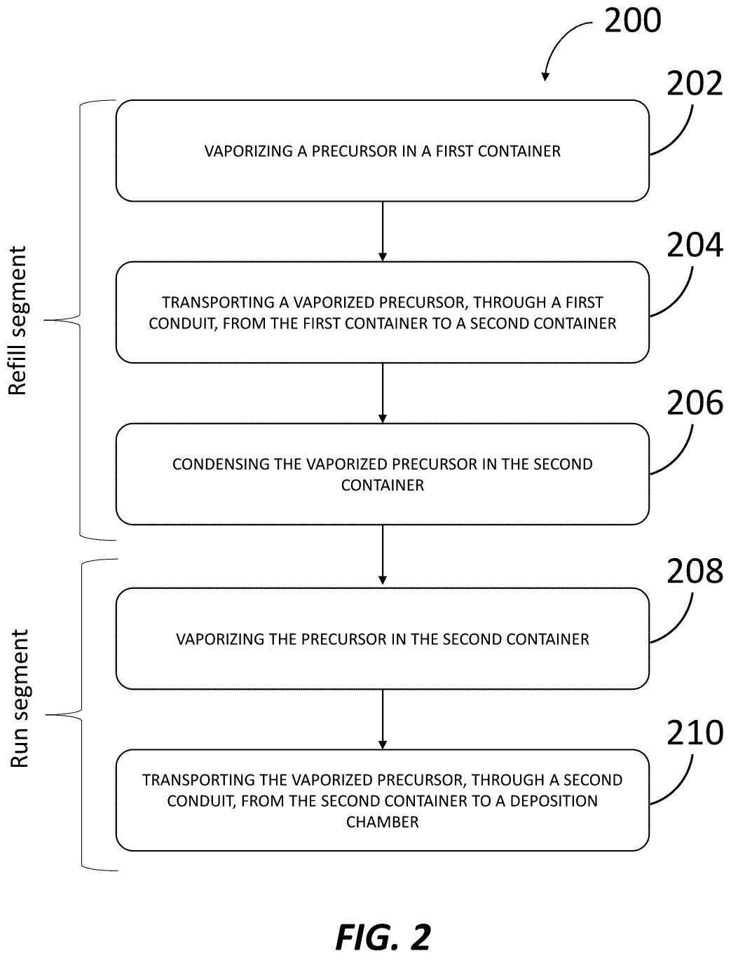

FIG. 2 is a flowchart of a method 200, according to some embodiments. As shown in FIG. 2, the method 200 comprises one or more of the following steps: vaporizing 202 a precursor in a first container; transporting 204 a vaporized precursor, through a first conduit, from the first container to a second container; condensing 206 the vaporized precursor in the second container; vaporizing 208 the precursor in the second container; and transporting 210 the vaporized precursor, through a second conduit, from the second container to a deposition chamber. In some embodiments, the method 200 is implemented using any one or more of the systems disclosed herein which are incorporated by reference herein in their entirety and which, for simplicity, are not repeated here. In some embodiments, at least one of steps 202, 204, 206, or any combination thereof, comprise a “refill segment.” In some embodiments, at least one of steps 208, 210, or any combination thereof, comprise a “run segment.”

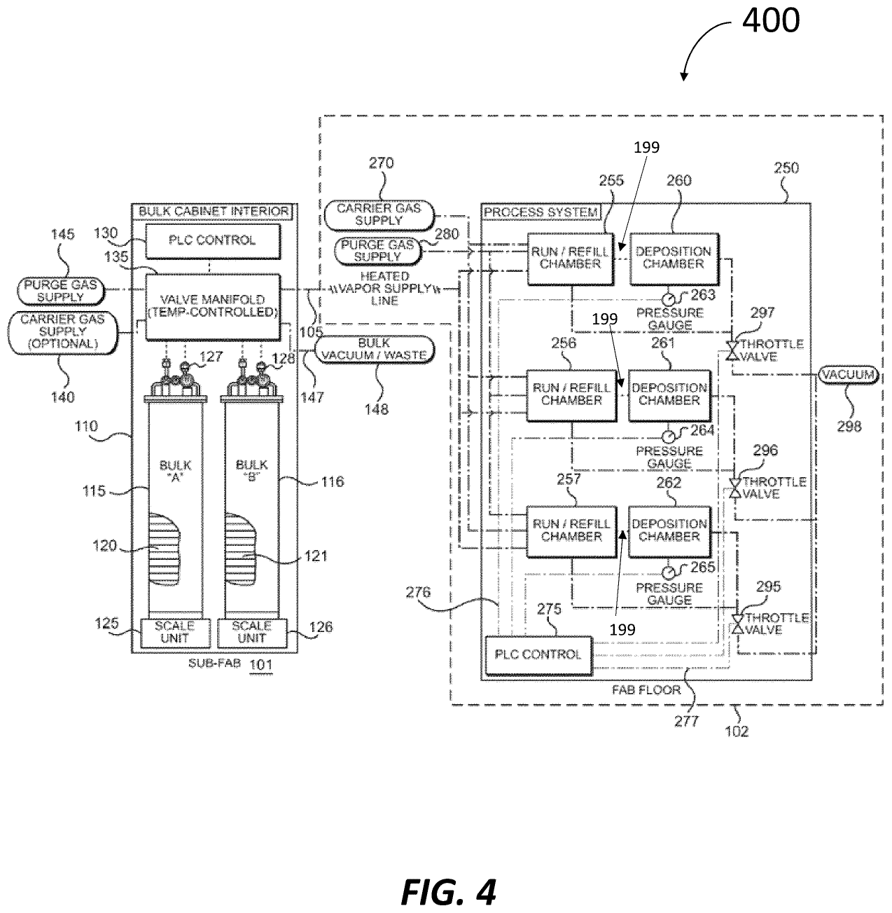

In some embodiments, steps 202, 204, and 206 may proceed continuously as a first segment, which may be referred to as a refill. During the refill, in some embodiments, the at least one first container 10 may be maintained at a temperature that is lower than a temperature of the first conduit 50, and higher than a temperature of the second container 20. In some embodiments, the first conduit 50 temperature is higher than the temperature of the first container 10 to prevent condensation in the first conduit 50. In some embodiments, the second container 20 has a lower temperature to promote condensation and storage of the precursor (solid precursor) in the second container 20. In some embodiments, after the desired amount of material is transferred into the second container 20, the first conduit 50 may be closed off with a valve. In some embodiments, steps 208 and 210 may then proceed continuously as a second segment, which may be referred to as the run segment. During the run segment, in some embodiments, the temperature of the second container 20 is increased to deliver the precursor vapor to the deposition chamber through the second conduit 60. In some embodiments, the temperature of the second conduit 60 is higher than the higher run temperature of the second container 20 to prevent condensation of precursor. In some embodiments, the flow of vapor from the run/refill to the deposition chamber can be controlled by a mass flow controller (MFC), or it can be controlled by a carrier gas supply 270 as presently shown in FIG. 4 (below).

At step 202, the method 200 comprises vaporizing a precursor in a first container. In some embodiments, the method 200 comprises vaporizing a precursor, in a first container located in an area outside a fabrication area, to obtain a first vaporized precursor. In some embodiments, the vaporizing comprises heating the precursor sufficient to obtain the vaporized precursor. In some embodiments, the vaporizing comprises pressurizing or depressurizing the container comprising the precursor sufficient to obtain the vaporized precursor. In some embodiments, the vaporizing comprises heating the first container comprising the precursor. In some embodiments, the vaporizing comprises heating the precursor by heating the first container. In some embodiments, the vaporizing comprises operating a thermal energy unit. In some embodiments, the vaporizing comprises heating at a temperature sufficient to vaporize the precursor to obtain the vaporized precursor. In some embodiments, the vaporizing comprises heating to a temperature below a decomposition temperature of at least one of the precursor, the vaporized precursor, or any combination thereof. In some embodiments, the precursor may be present in a gas phase, in which case this step is optional and not required. For example, the precursor may comprise the vaporized precursor.

At step 204, the method 200 comprises transporting a vaporized precursor, through a first conduit, from the first container to a second container. In some embodiments, the method 200 comprises transporting, at a first temperature, the first vaporized precursor through a first conduit to a second container located in an area in the fabrication area. In some embodiments, the transporting comprises conveying the vaporized precursor, through a first conduit, from the first container to a second container. In some embodiments, the transporting comprises pumping the vaporized precursor, through a first conduit, from the first container to a second container. In some embodiments, the transporting comprises drawing (e.g., under vacuum) the vaporized precursor, through a first conduit, from the first container to a second container. In some embodiments, the transporting comprises flowing the vaporized precursor, through a first conduit, from the first container to a second container. In some embodiments, the transporting comprises opening an outlet and/or a valve the vaporized precursor, through a first conduit, from the first container to a second container. In some embodiments, the transporting comprises coflowing with a carrier gas the vaporized precursor, through a first conduit, from the first container to a second container.

At step 206, the method 200 comprises condensing the vaporized precursor in the second container. In some embodiments, the method 200 comprises condensing the first vaporized precursor in the second container to obtain a solid precursor. In some embodiments, the condensing comprises cooling the vaporized precursor to a temperature sufficient to condense the vaporized precursor. In some embodiments, the condensing comprises cooling the second container to a temperature sufficient to condense the vaporized precursor. In some embodiments, the condensing comprises pressurizing or depressurizing the second container to a pressure sufficient to condense the vaporized precursor. In some embodiments, the temperature and/or pressure sufficient for condensing the vaporized precursor is a temperature and/or a pressure below the condensation conditions (e.g., temperature and/or pressure) for the vaporized precursor.

At step 208, the method 200 comprises vaporizing the precursor in the second container. In some embodiments, the method 200 comprises vaporizing the solid precursor, in the second container, to obtain a second vaporized precursor. In some embodiments, the vaporizing comprises heating the precursor sufficient to obtain the vaporized precursor. In some embodiments, the vaporizing comprises pressurizing or depressurizing the container comprising the precursor sufficient to obtain the vaporized precursor. In some embodiments, the vaporizing comprises heating the second container comprising the precursor. In some embodiments, the vaporizing comprises heating the precursor by heating the second container. In some embodiments, the vaporizing comprises operating a thermal energy unit. In some embodiments, the vaporizing comprises heating at a temperature sufficient to vaporize the precursor to obtain the vaporized precursor. In some embodiments, the vaporizing comprises heating to a temperature below a decomposition temperature of at least one of the precursor, the vaporized precursor, or any combination thereof. In some embodiments, the precursor may be present in a gas phase, in which case this step is optional and not required. For example, the precursor may comprise the vaporized precursor.

At step 210, the method 200 comprises transporting the vaporized precursor, through a second conduit, from the second container to a deposition chamber. In some embodiments, the method 200 comprises transporting, at a second temperature, the second vaporized precursor through a second conduit to at least one deposition chamber located in an area in the fabrication area. In some embodiments, the transporting comprises conveying the vaporized precursor, through a second conduit, from the second container to a deposition chamber. In some embodiments, the transporting comprises pumping the vaporized precursor, through a second conduit, from the second container to a deposition chamber. In some embodiments, the transporting comprises drawing (e.g., under vacuum) the vaporized precursor, through a second conduit, from the second container to a deposition chamber. In some embodiments, the transporting comprises flowing the vaporized precursor, through a second conduit, from the second container to a deposition chamber. In some embodiments, the transporting comprises opening an outlet and/or a valve the vaporized precursor, through a second conduit, from the second container to a deposition chamber. In some embodiments, the transporting comprises coflowing with a carrier gas the vaporized precursor, through a second conduit, from the second container to a deposition chamber.

In some embodiments, the method 200 further comprises contacting at least one of the vaporized precursor, at least one vaporized co-reactant precursor, or any combination thereof, with a substrate, under vapor deposition conditions, sufficient to form a film on a surface of the substrate. The contacting may be performed in any system, apparatus, device, assembly, chamber thereof, or component thereof suitable for vapor deposition processes, including, for example and without limitation, a deposition chamber, among others. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The substrate may comprise, consist of, or consist essentially of at least one of Si, Co, Cu, Al, W, WN, WC, TIN, Mo, MOC, Mo₂N, SiO₂, W, SIN, WCN, Al₂O₃, AlN, ZrO₂, La₂O₃, TaN, RuO₂, IrO₂, Nb₂O₃, Y₂O₃, hafnium oxide, or any combination thereof. In some embodiments, the silicon-containing film may comprise, consist of, or consist essentially of at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

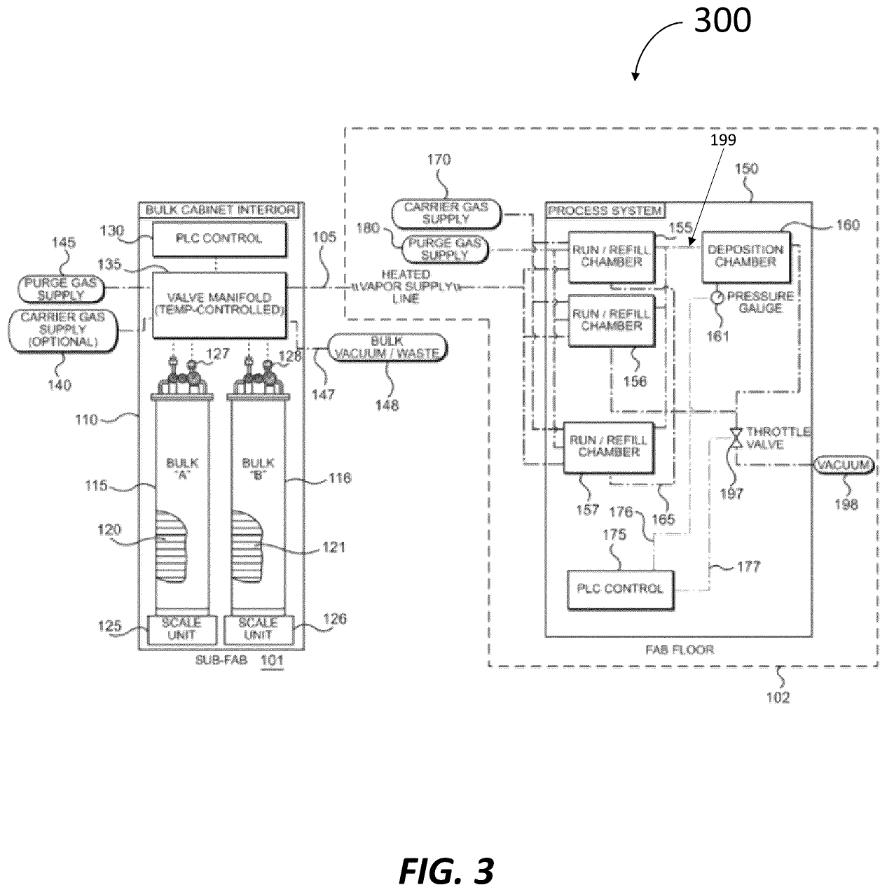

FIG. 3 is a schematic diagram of a system 300, according to some embodiments. One portion of system 300 is located in a sub-fabrication area 101, hereinafter a sub-fab, while another portion is located in a fabrication area or floor 102 which is shown as enclosed by a dashed line, hereinafter a fab. These portions are connected by a heated vapor supply line (or first conduit) 105. A cabinet 110 is preferably located in the sub-fab but could be located in a more remote location. The cabinet 110 houses a first container 115 and a second container 116. In some embodiments, containers 115 and 116 and their internal support structures are made of 316L stainless steel that is electro-polished. The 316L stainless steel is preferably coated with a thin film of a more resistant material for each specific chemistry, e.g., nickel, aluminum oxide, etc. In some embodiments, a metal alloy material can be employed. Inconel, Hastelloy C276, C22, Alloy 20, etc. are examples of such alloys. Also, different materials can be employed. For example, the containers can be made of 316L stainless steel, and the internal support structure can be made of a more resistant alloy or coated with a more resistant alloy. It will be appreciated that the cabinet 110 may comprise only a single container, or the cabinet 110 may comprise more than the first container 115 and the second container 116. For example, in some embodiments, the cabinet 110 may comprise a third container, a fourth container, a fifth container, a sixth container, a seventh container, an eighth container, a ninth container, a tenth container, or more than ten containers.

A precursor 120 is stored within container 115 in solid form, and a precursor 121 is stored within container 116 in solid form. Although different reference numerals are used, precursors 120 and 121 are typically the same material. In use, container 115, for example, is used until precursor 120 is depleted. Then, container 116 is used while container 115 is being replaced or refilled. After precursor 121 is depleted, container 115 is used while container 116 is being replaced or refilled. Accordingly, there is no downtime in this portion of the process. A first scale unit 125 and a second scale unit 126 are configured to weigh containers 115 and 116 to provide information regarding the amount of precursor 120 remaining within container 115 and the amount of precursor 121 remaining within container 116. Connection lines 127 and 128 allow for the precursor vapor to leave containers 115 and 116. Containers 115 and 116 can also employ additional monitoring features to monitor multiple temperature zones, vacuum level, mass delivery rate to first conduit 105, internal/external filtration, internal/external purification, impurity levels, etc. A programmable logic controller 130 controls a manifold 135 to regulate the transport of precursors 120 and 121 from containers 115 and 116 to the fab. Specifically, precursors 120 and 121 are heated in containers 115 and 116 to cause sublimation and the resulting vapor is transported to fab 102 via vapor supply line 105, optionally using a carrier gas supplied by a carrier gas supply 140. In some embodiments, no carrier gas is used as the transport is achieved by drawing vapor through the vapor supply line (e.g., under vacuum). The conditions of the first conduit or vapor supply line 105 can include any of the conditions disclosed herein and generally include a temperature and/or a pressure that is less than a temperature and/or a pressure of line 199. Supply line 105 is preferably also heated at or above the temperature of the precursor in containers 115 or 116 and monitored to measure precursor delivery rate. Precursors 120 and 121 are not typically transported through vapor supply line 105 at the same time. Instead, precursors 120 and 121 are preferably transported in an alternating fashion, as discussed above. A purge gas supplied by a purge gas supply 145 is used to purge the conduits through which precursors 120 and 121 pass (e.g., vapor supply line 105). The purge is preferably conducted with an automated cycle to remove potential chemical material from line 105 as it leaves containers 115 and 116 through connectors that are not separately labeled. Waste is removed from manifold 135 through a line 147 to a vacuum disposal unit 148. Line 147 can also be heated to limit condensation of waste product. As an alternative delivery method, containers 115 and 116 could be used in series or parallel with the proper manifolding. The manifolding would still allow a single container to provide vapor to the run/refill chambers while the other container is replaced. The option of series or parallel delivery would allow for more complete consumption of the precursor while not impacting the quantity of vapor available to the run/refill chambers. This alternative would reduce the amount of residual precursor in the container and would improve the cost of ownership.

A process system 150 is located in fab 102. Process system 150 includes a plurality of run/refill chambers 155-157, which receive precursors 120 and 121 from vapor supply line 105. In particular, precursors 120 and 121 enter run/refill chambers 155-157 as a vapor and are then solidified, or deposited, within run/refill chambers 155-157 as a solid by cooling run/refill chambers 155-157. For purposes of the present invention, the term “deposition”, and variants thereof, refers to the chemical vapor deposition (CVD) process whereby a precursor gas is chemically converted to a solid film rather than the more general act of putting an object in specific location. Precursors 120 and 121 are stored within run/refill chambers 155-157 in solid form. When needed, precursor 120, 121 is sublimated within one of run/refill chambers 155-157 by heating the corresponding run/refill chamber 155-157. The run refill chambers 155-157 are preferably heated and cooled rapidly between a run mode to the chamber and a refill mode to condense solids. Heating and cooling is preferably accomplished using one of several techniques including resistive heating, hot oil recirculation and radiant heating. Cooling can be done by chilled water, glycol, heat transfer fluid, a Peltier cooling device, Joule-Thompson cooling, etc. Precursor 120, 121 is then transported to a deposition chamber 160, which is preferably in close proximity to run/refill chambers 155-157 and includes a pressure gauge 161. Alternatively, precursor 120, 121 is transported to a second run/refill chamber 155-157. A conduit 165 connects chambers 155-157 to a vacuum. In the first scenario, the chosen one of precursors 120 and 121 is used to deposit a film on a substrate (not shown) located within deposition chamber 160. Additional co-reactant and inert gases are generally part of a CVD or ALD process. These are not shown but are delivered using conventional hardware including mass flow controllers (MFCs) and pressure controllers (PCs). In an atomic layer deposition (ALD) process, the delivery of the co-reactant gas is separated in time from the delivery of the precursor vapor. An optional carrier gas supply 170 can be used to transport precursors 120 and 121 within process system 150, while a programmable logic controller 175 controls process system 150. More specifically, controller 175 is connected through control lines 176 and 177 to gauge 161 and control valve 197 and is able to measure and control pressure in chamber 160 by opening valve 197, which leads to vacuum 198. A purge gas supplied by a purge gas supply 180 is used to purge run/refill chambers 155-157.

It will be appreciated that, although the deposition chamber 160 is in fluid communication with three run/refill chambers (i.e., run/refill chambers 155-157), the system 300 may comprise other configurations and quantities of run/refill chambers and deposition chambers. For example, in some embodiments, the system 300 comprises one or more of the following: a first run/refill chamber and a second run/refill chamber in fluid communication with a first deposition chamber; a third run/refill chamber and a fourth run/refill chamber in fluid communication with a second deposition chamber; a fifth run/refill chamber and a sixth run/refill chamber in fluid communication with a third deposition chamber; and so on. In some embodiments, the deposition chamber is in fluid communication with only a single run/refill chamber or more than two run/refill chambers (e.g., three run/refill chambers to ten or more run/refill chambers). In some embodiments, the system 300 comprises more than three deposition chambers (e.g., four deposition chambers to ten or more deposition chambers).

In some embodiments, each of run/refill chambers 155-157 is sized to hold an amount of precursor 120 or 121 sufficient for one deposition cycle but not two deposition cycles. In other embodiments, each of run/refill chambers 155-157 is sized to hold an amount of precursor 120 or 121 sufficient for a plurality of deposition cycles. The term “deposition cycle” refers to the steps by which a single layer of a film is deposited on a substrate. Although run/refill chambers 155-157 are labeled with different reference numerals, run/refill chambers 155-157 can be identical to one another.

The term “run/refill” means “run and/or refill”. A chamber (e.g., chamber 155) is being refilled when it is at its lower temperature setting and vapor is entering via vapor supply line 105 and condensing on the high surface area interior. Then, the chamber is running when it is at its higher temperature setting and the solid that had condensed during the refill part of the cycle is evaporated and the vapor is delivered to the deposition chamber via a line 199. The conditions of the line 199 (e.g., second conduit) can include any of the conditions disclosed herein and generally include a temperature and/or a pressure that is greater than a temperature and/or a pressure of line 105. The term “run/refill chamber” indicates that the chamber acts as both run and refill chambers. The run/refill chamber can incorporate filtration, purification, pressure/vacuum monitoring and delivery rate or solids film sensing. The run/refill chamber is preferably designed to be cycled for every wafer, or one “refill” of the run/refill chamber is designed to provide vapor for two or more wafers before getting “refilled” again.

FIG. 4 is a schematic diagram of a system 400, according to some embodiments. System 400 generally functions in the same manner as system 300 except that system 400 has one run/refill chamber per deposition chamber. Specifically, a process system 250 includes a plurality of run/refill chambers 255-257, which receive precursors 120 and 121 from vapor supply line 105. The conditions of the first conduit or vapor supply line 105 can include any of the conditions disclosed herein and generally include a temperature and/or a pressure that is less than a temperature and/or a pressure of line 199. Precursors 120 and 121 enter run/refill chambers 255-257 as a vapor and are then deposited within run/refill chambers 255-257 as a solid by cooling run/refill chambers 255-257. When needed, precursor 120 or 121 is sublimated within one of run/refill chambers 255-257 by heating that run/refill chamber 255-257. Precursor 120 or 121 is then transported to a corresponding one of a plurality of deposition chambers 260-262 via lines 199. Precursor 120 or 121 is used to deposit a film on a substrate (not shown) located within the corresponding deposition chamber 260-262. An optional carrier gas supply 270 can be used to transport precursors 120 and 121 within process system 250, while a controller 275 controls process system 250. Controller 275 is connected to gauges 263-265 through control lines 276. Controller 275 is also connected through lines 277 to control valves 295-297 and is able to measure and control pressure in chambers 260-262 by opening valves 295-297, which lead to vacuum 298. A purge gas supplied by a purge gas supply 280 is used to purge run/refill chambers 255-257. In some embodiments, the precursors 120 and 121 are transported under a vapor draw configuration.

In some embodiments, the carrier gas supply 270 is removed from the system 400. In some embodiments, a mass flow controller (MFC) (not shown) is added to the delivery line 199 located between the run/refill chamber 255 and the deposition chamber 260.

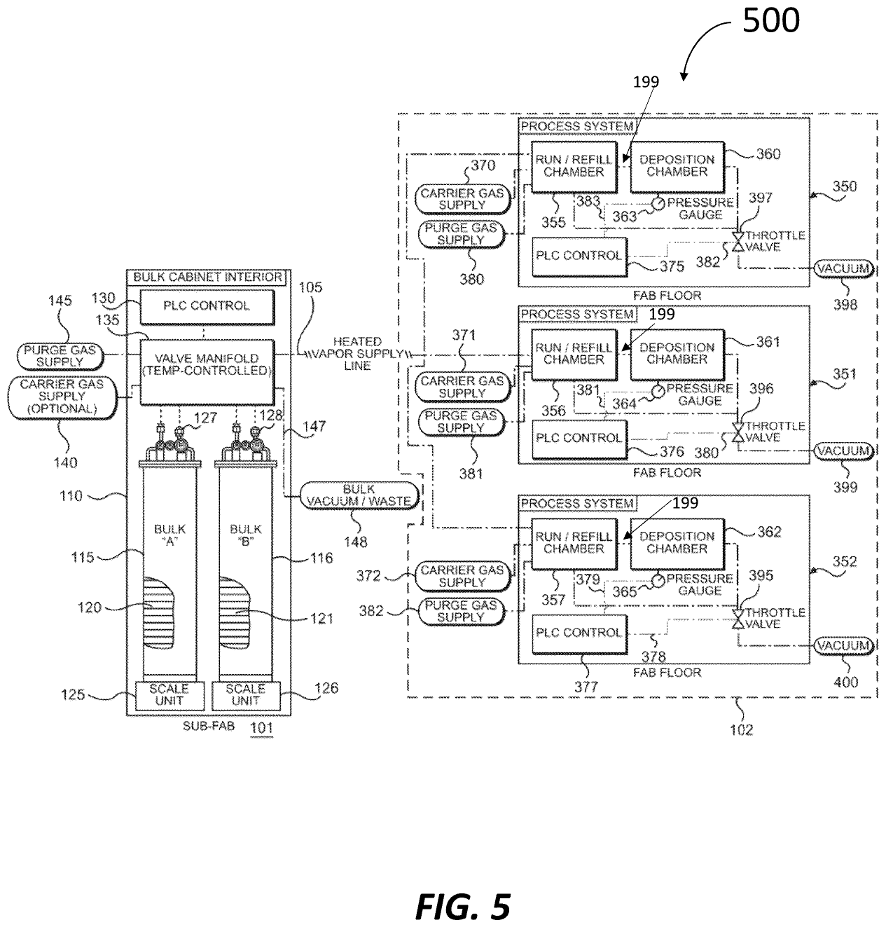

FIG. 5 is a schematic diagram of a system 500, according to some embodiments. System 500 generally functions in the same manner as systems 300 and 400 except that system 500 includes a plurality of process systems 350-352. Each process system 350-352 includes a run/refill chamber 355-357, which receives precursors 120 and 121 from vapor supply line 105. The conditions of the first conduit or vapor supply line 105 can include any of the conditions disclosed herein and generally include a temperature and/or a pressure that is less than a temperature and/or a pressure of line 199. Precursors 120 and 121 enter run/refill chambers 355-357 as a vapor and are then deposited within run/refill chambers 355-357 as a solid by cooling run/refill chambers 355-357. When needed, precursor 120 or 121 is sublimated within one of run/refill chambers 355-357 by heating that run/refill chamber 355-357. Precursor 120 or 121 is then transported to a corresponding deposition chamber 360-362 via lines 199. Precursor 120 or 121 is used to deposit a film on a substrate (not shown) located within that deposition chamber 360-362. Optional carrier gas supplies 370-372 can be used to transport precursors 120 and 121 within process systems 350-352, while controllers 375-377 control process systems 350-352. More specifically, controllers 375-377 are connected to gauges 363-365 through control lines of which lines 378-383 are labeled. Controllers 375-377 are also connected to control valves 395-397 and are able to measure and control pressure in chambers 360-362 by opening valves 395-397, which lead to vacuum at 398-400. A purge gas supplied by purge gas supplies 380-382 is used to purge run/refill chambers 355-357. In some embodiments, the precursors 120 and 121 are transported under a vapor draw configuration.

### Example 1

30 kg of MoO₂Cl₂ solid precursor is loaded into an ampoule (Entegris PE600 in an Entegris SSDC) located in a non-fabrication area, or “subfab.” During a refill segment, the ampoule is maintained at 100° C., the conduit to the fabrication area (“fab area”) is maintained at 120° C., and the run/refill chamber, which is located in the fabrication area, is maintained at 90° C., with the flow rate set at about 200 sccm such that it accumulates about 2 kg of MoO₂Cl₂ over about 20 hours. Over the next 2 hours, the temperature of the run/refill chamber is increased to 135° C. and the conduit to the deposition chamber is maintained at 155° C. Under this condition, the run/refill chamber delivers up to 1000 sccm pulses of MoO₂Cl₂ vapor to the deposition chamber as demanded through a mass flow controller (MFC) during the run segment. At the end of the deposition/run segment, excess material from the run/refill chamber is sent to scrubber/waste, bypassing the deposition chamber. Subsequent refill segments are performed under similar conditions. As there were 2 run/refill chambers at each deposition chamber, one is being refilled while the other is being used to deposit films in the deposition chamber.

### Aspects

Various Aspects are described below. It is to be understood that any one or more of the features recited in the following Aspect(s) can be combined with any one or more other Aspect(s).
Aspect 1. A system comprising:
   at least one first container;
   at least one second container;
   at least one deposition chamber;
   a first conduit connecting the at least one first container to the at least one second container; and
   a second conduit connecting the at least one second container to the at least one deposition chamber;
      wherein the first conduit is configured for delivering a vaporized precursor, at a first temperature, from the at least one first container to the at least one second container;
      wherein the second conduit is configured for delivering the vaporized precursor, at a second temperature, from the at least one second container to the at least one deposition chamber;
         wherein the first temperature is less than the second temperature.
Aspect 2. The system according to Aspect 1,
   wherein the at least one first container is located in a non-fabrication area;
   wherein the at least one second container is located in a fabrication area;
   wherein the at least one deposition chamber is located in the fabrication area.
Aspect 3. The system according to any one of Aspects 1-2, wherein the first conduit has a length that is greater than a length of the second conduit.
Aspect 4. The system according to any one of Aspects 1-3, wherein the first conduit has a length that is at least 2 times greater than a length of the second conduit.
Aspect 5. The system according to any one of Aspects 1-4, wherein the first temperature is a first set point temperature, wherein the second temperature is a second set point temperature, wherein the first set point temperature is at least 5° C. less than the second set point temperature.
Aspect 6. The system according to any one of Aspects 1-5, wherein the first temperature is a first set point temperature, wherein the second temperature is a second set point temperature, wherein the first set point temperature is at least 10° C. less than the second set point temperature.
Aspect 7. The system according to any one of Aspects 1-6, wherein the first temperature is a first set point temperature, wherein the second temperature is a second set point temperature, wherein the first set point temperature is 20° C. to 30° C. less than the second set point temperature.
Aspect 8. The system according to any one of Aspects 1-7, further comprising:
   a plurality of temperature controllers located along a length of the first conduit,
      wherein each of the plurality of temperature controllers is located at least 5 feet apart along a length of the first conduit,
      wherein each of the plurality of temperature controllers is configured to maintain the first conduit at the first temperature,
         wherein the first temperature is a first set point temperature.
Aspect 9. The system according to any one of Aspects 1-8, further comprising at least one vacuum, wherein the at least one vacuum is connected to at least one of the first conduit, the second conduit, or any combination thereof, wherein the at least one vacuum is configured for drawing the vaporized precursor through at least one of the first conduit, the second conduit, or any combination thereof.
Aspect 10. A system comprising:
   at least one first container;
   at least one second container;
   at least one deposition chamber;
   a first conduit connecting the at least one first container to the at least one second container; and
   a second conduit connecting the at least one second container to the at least one deposition chamber;
      wherein the first conduit is configured for delivering a vaporized precursor, at a first pressure, from the at least one first container to the at least one second container;
      wherein the second conduit is configured for delivering the vaporized precursor, at a second pressure, from the at least one second container to the at least one deposition chamber;
         wherein the first pressure is less than the second pressure.
Aspect 11. The system according to Aspect 10,
   wherein the at least one first container is located outside a fabrication area;
   wherein the at least one second container is located in the fabrication area;
   wherein the at least one deposition chamber is located in the fabrication area.
Aspect 12. The system according to any one of Aspects 10-11, wherein the first conduit has a length that is greater than a length of the second conduit.
Aspect 13. The system according to any one of Aspects 10-12, wherein the first conduit has a length that is at least 2 times a length of the second conduit.
Aspect 14. The system according to any one of Aspects 10-13, wherein the first pressure is a first set point pressure, wherein the second pressure is a second set point pressure, wherein the first set point pressure is at least 10% less than the second set point pressure.
Aspect 15. The system according to any one of Aspects 10-14, wherein the first pressure is a first set point pressure, wherein the second pressure is a second set point pressure, wherein the first set point pressure is at least 15% less than the second set point pressure.
Aspect 16. The system according to any one of Aspects 10-15, further comprising at least one vacuum, wherein the at least one vacuum is connected to at least one of the first conduit, the second conduit, or any combination thereof, wherein the at least one vacuum is configured for drawing the vaporized precursor through at least one of the first conduit, the second conduit, or any combination thereof.
Aspect 17. A method comprising:
   vaporizing a precursor, in a first container located in an area outside a fabrication area, to obtain a first vaporized precursor;
   transporting, at a first temperature, the first vaporized precursor through a first conduit to a second container located in an area in the fabrication area;
   condensing the first vaporized precursor in the second container to obtain a solid precursor;
   vaporizing the solid precursor, in the second container, to obtain a second vaporized precursor; and
   transporting, at a second temperature, the second vaporized precursor through a second conduit to at least one deposition chamber located in an area in the fabrication area.
Aspect 18. The method according to Aspect 17, wherein the first conduit has a length that is greater than a length of the second conduit.
Aspect 19. The method according to any one of Aspects 17-18, wherein the first conduit has a length that is at least 2 times a length of the second conduit.
Aspect 20. The method according to any one of Aspects 17-19, wherein the first temperature is at least 10% less than the second temperature.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system comprising:
at least one first container;
at least one second container;
at least one deposition chamber;
a first conduit connecting the at least one first container to the at least one second container; and
a second conduit connecting the at least one second container to the at least one deposition chamber;
wherein the first conduit is configured for delivering a vaporized precursor, at a first temperature, from the at least one first container to the at least one second container;
wherein the second conduit is configured for delivering the vaporized precursor, at a second temperature, from the at least one second container to the at least one deposition chamber;
wherein the first temperature is less than the second temperature.

2. The system of claim 1,
wherein the at least one first container is located in a non-fabrication area;
wherein the at least one second container is located in a fabrication area;
wherein the at least one deposition chamber is located in the fabrication area.

3. The system of claim 1, wherein the first conduit has a length that is greater than a length of the second conduit.

4. The system of claim 1, wherein the first conduit has a length that is at least 2 times greater than a length of the second conduit.

5. The system of claim 1, wherein the first temperature is a first set point temperature, wherein the second temperature is a second set point temperature, wherein the first set point temperature is at least 5° C. less than the second set point temperature.

6. The system of claim 1, wherein the first temperature is a first set point temperature, wherein the second temperature is a second set point temperature, wherein the first set point temperature is at least 10° C. less than the second set point temperature.

7. The system of claim 1, wherein the first temperature is a first set point temperature, wherein the second temperature is a second set point temperature, wherein the first set point temperature is 20° C. to 60° C. less than the second set point temperature.

8. The system of claim 1, further comprising:
a plurality of temperature controllers located along a length of the first conduit,
wherein each of the plurality of temperature controllers is located at least 5 feet apart along a length of the first conduit,
wherein each of the plurality of temperature controllers is configured to maintain the first conduit at the first temperature,
wherein the first temperature is a first set point temperature.

9. The system of claim 1, further comprising at least one vacuum, wherein the at least one vacuum is connected to at least one of the first conduit, the second conduit, or any combination thereof, wherein the at least one vacuum is configured for drawing the vaporized precursor through at least one of the first conduit, the second conduit, or any combination thereof.

10. A system comprising:
at least one first container;
at least one second container;
at least one deposition chamber;
a first conduit connecting the at least one first container to the at least one second container; and
a second conduit connecting the at least one second container to the at least one deposition chamber;
wherein the first conduit is configured for delivering a vaporized precursor, at a first pressure, from the at least one first container to the at least one second container;
wherein the second conduit is configured for delivering the vaporized precursor, at a second pressure, from the at least one second container to the at least one deposition chamber;
wherein the first pressure is less than the second pressure.

11. The system of claim 10,
wherein the at least one first container is located outside a fabrication area;
wherein the at least one second container is located in the fabrication area;
wherein the at least one deposition chamber is located in the fabrication area.

12. The system of claim 10, wherein the first conduit has a length that is greater than a length of the second conduit.

13. The system of claim 10, wherein the first conduit has a length that is at least 2 times a length of the second conduit.

14. The system of claim 10, wherein the first pressure is a first set point pressure, wherein the second pressure is a second set point pressure, wherein the first set point pressure is at least 10% less than the second set point pressure.

15. The system of claim 10, wherein the first pressure is a first set point pressure, wherein the second pressure is a second set point pressure, wherein the first set point pressure is at least 15% less than the second set point pressure.

16. The system of claim 10, further comprising at least one vacuum, wherein the at least one vacuum is connected to at least one of the first conduit, the second conduit, or any combination thereof, wherein the at least one vacuum is configured for drawing the vaporized precursor through at least one of the first conduit, the second conduit, or any combination thereof.

17. A method comprising:
vaporizing a precursor, in a first container located in an area outside a fabrication area, to obtain a first vaporized precursor;
transporting, at a first temperature, the first vaporized precursor through a first conduit to a second container located in an area in the fabrication area;
condensing the first vaporized precursor in the second container to obtain a solid precursor;
vaporizing the solid precursor, in the second container, to obtain a second vaporized precursor; and
transporting, at a second temperature, the second vaporized precursor through a second conduit to at least one deposition chamber located in an area in the fabrication area.

18. The method of claim 17, wherein the first conduit has a length that is greater than a length of the second conduit.

19. The method of claim 17, wherein the first conduit has a length that is at least 2 times a length of the second conduit.

20. The method of claim 17, wherein the first temperature is at least 10% less than the second temperature.
